(19) United States
(12) Patent Application Publication
(10) Pub. No.: US 2004/0232944 A1
(43) Pub. Date: Nov. 25, 2004

(54) Dynamic CMOS level-shifting circuit apparatus

(76) Inventors: Linkai Bu, Tainan (TW); Chuan-Cheng Hsiao, Jiayi (TW); Kun-Cheng Hung, Hsinchu (TW); Chien-Pin Chen, Tainan (TW)

Correspondence Address: BAKER & MCKENZIE, PATENT DEPARTMENT, 2001 ROSS AVENUE, SUITE 2300, DALLAS, TX, 75201, US

(21) Appl. No.: 09/765,966

(22) Filed: Jan. 19, 2001

(30) Foreign Application Priority Data
Dec. 7, 2000 (TW) 89126108

(51) Int. Cl. H03K 19/094

(52) U.S. Cl. 326/68

(57) ABSTRACT

A dynamic CMOS level shifter circuit apparatus in a digital electronic system is disclosed for shifting a signal of a first logic family at a first lower voltage level to a second higher voltage level for a second logic family. The shifter circuit apparatus comprises a first transistor pair that has a first PMOS and a first NMOS transistor connected in series; a second transistor pair that has a second PMOS and a second NMOS transistor connected in series; and a power-down control PMOS transistor. The first and second transistor pairs are connected in parallel, and the parallel connection is connected in series with the power-down control PMOS transistor across the power and ground level of the system. The node at which the drain terminals of the transistors of the first transistor pair is connected together is also connected to the gate of the second PMOS transistor. The node at which the drain terminals of the transistors of the second transistor pair is connected together is also connected to the gate of the first PMOS transistor. Further, the gate terminal of the first NMOS transistor serves as the signal input for the input logic family, and the gate terminal of the first PMOS transistor serves as the shifted output of the shifter circuit apparatus.

### FIELD OF THE INVENTION

This invention relates generally to voltage level shifting in digital electronic systems. More particularly, this invention relates to a dynamic CMOS level-shifting circuit apparatus for switching signal voltage level in digital electronic systems.

### BACKGROUND OF THE INVENTION

Voltage level shifting of electronic signals is essential in many digital electronic systems. In a digital electronic system, level-shifting becomes necessary whenever two or more families of logic circuitry with different operating signal voltage ratings are required to interface with one another. For example, a microprocessor of a digital system operating at 3.3V needs to shift its output signals at 3.3V to 5V in order to be compatible with TTL logic in other sections of the system.

This is inevitable in, for example, a digital system such as the personal computer. The microprocessor for PC is constantly improved with ever higher speed for pursuing ever larger processing power. However, lower operating voltage is necessary in order to reduce power consumption and therefore alleviate the problem of heat dissipation in these high-performance microprocessors. Lower operating voltage ensures lower power consumption, which is one of the most important design considerations in mobile digital systems. On the other hand, essential subsystems of a PC, such as devices connected to the PCI and ISA buses, have standard signal voltage ratings of 3.3V and 5V respectively. A high-performance microprocessor for a PCI-based PC may be operating at 2V. For the microprocessor to interface with the PCI and ISA subsystsms, the level-shifting circuitry become indispensable.

In another example, a TFT LCD (Thin-Film Transistor Liquid Crystal Display) has an array of transistors that require a relatively higher operating voltage of about 12V than the rest of the computer system, with which it is integrated. For the computer display subsystem operating typically below 5V to interface with the transistor matrix of the TFT LCD, a level shifter circuit is required. Such a shifter would have to shift the 5V signal of the display subsystem to 12V that operates the TFT LCD.

In still another example, typical EEPROM (Electrically Erasable-Programmable Read-Only Memory) devices have a programming voltage of at least 12V that is substantially higher than their normal operating voltage of 5 or 3.3V. Whenever an EEPROM device requires programming, a shifter is needed to interface 3.3 or 5V to 12V. Many other applications requiring the use of a signal voltage shifter circuitry are easily enumerable.

FIG. 1 is a schematic diagram showing the circuit configuration of a typical prior-art level shifter. Such a shifter circuit 100 may be used for shifting signals from one lower voltage level to a higher one for two logic families of a digital system. In such a system, the level shifter 100 raises the lower operating signal voltage of the first logic family at its input 101 (IN) to the higher one for the second at its output 103 (OUT).

The level shifter 100 is composed of two pairs of P- and NMOS FET's as is generally indicated by reference numerals 110 and 120 in the drawing. The first pair 110 has a PMOS FET 111 connected in series with an NMOS FET 112, and the series pair is connected across the power V_{DD2} and the ground GND voltages of the system. In a similar arrangement, the second pair 120 having a PMOS FET 121 in series with an NMOS FET 122 is also tied directly across V_{DD2} and GND. Essentially, the two P- and NMOS transistor pairs 110 and 120 are connected in parallel across the power V_{DD2} and ground GND voltage levels.

In both series pairs, the PMOS FET is connected at the power end, and the NMOS at the ground end. The P- and NMOS FET's in each pair have their respective drains connected together, the source of the PMOS FET's connected to the power, and that of the NMOS FET's to the ground.

The node at which the drain terminals of one series pair of FET's are connected is also connected to the gate of the PMOS FET of the other FET pair, as is identified as the 104 and 103 nodes (\overline{OUT} and OUT) for the first and second pairs respectively. The gate terminal of the NMOS FET 112 of the first pairs 110 serves as the signal input node 101 (IN) for the input logic family. Gate terminal of the NMOS FET 122 of the second pair 120, by contrast, is the inverted signal input node 102 (\overline{IN}). The common node where the drain terminals of the FET's 121 and 122 of the second pair 120 are connected together serves as the output node 103 (OUT) of the level shifter 100. By contrast, the node of the joined drain terminals of FET's 111 and 112 of the first pair 110 is the reversed output 104 (\overline{OUT}) of the shifter.

In the circuit configuration of the conventional level shifter 100 of FIG. 1, the NMOS FET's 112 and 114 must be sufficiently and much stronger than their corresponding PMOS counterparts 111 and 113 if the voltage difference between the input and the shifted output signals are relatively large. This is in order to break the positive feedback loop formed in the circuit 100 so that a transition of state in the transistor devices may take place. Consider, for example, the situation wherein V_{DD2} is 5V, V_{DD1} 3.3V, and V_{T}, the threshold voltage of the devices, 1V. Note that V_{DD2} and V_{DD1} in this case are the power voltages of the high and low voltage-level logic systems respectively. The drain current I_{N} of the NMOS FET's can then be determined by the expression

I_{N}=k_{N}(V_{DD1}−V_{T})²=5.29 k_{N}.

On the other hand, the drain current of the PMOS FET's can be determined by

I_{P}=k_{P}(V_{DD2}−V_{T})²=16 k_{P},

wherein k_{N} and k_{P} are the transconductance parameters of the N- and PMOS devices respectively.

Compare the above two transconductance parameters for the N- and PMOS devices in a 3.3V-to-5V system. It is clear that k_{N} must be about at least 3 times larger than k_{P} (16/5.29=3.02) in order to ensure state transition in the shifter 100. If the shifted output voltage targeted is substantially larger than the input signal, this difference becomes even more excessive. For example, in a system having a 12V V_{DD2} such as for transistors in a TFT LCD transistor matrix, k_{N} would be about 23 times as large as k_{P} (121/5.29=22.87).

Further, the transition current of the shifter transistor also increases as the device size. Although a dynamic shifter such as the prior-art one depicted in FIG. 1 based on CMOS logic enjoys virtually zero steady-state current, however, for applications such as TFT LCD, excessive transition current becomes a major concern for power conservation. This is particularly true for battery-powered portable devices. In the above-described example, the current consumption with a 12V V_{DD2} is 7.56 times larger than when it is 5V ((12−1)²/(5−1)²=7.56). When it translates into power consumption, the power consumed by the larger transistor device is about more than 18 times as large as that by the smaller device (power consumed=VI=(12(12−1)²)1(5(5−1)²)=18.15).

Thus, it is evident that such a conventional level shifter circuitry as illustrated in FIG. 1 has at least two drawbacks when the voltage difference between the shifted signals becomes relatively large. First, some of the transistor devices in the circuitry have to be fabricated asymmetrically large relative to the others since much larger current must be handled. Second, as a result of relatively excessive current, the transition power consumed also becomes excessively and asymmetrically large.

It is therefore an object of the invention to provide a dynamic CMOS level shifter circuit apparatus capable of shifting a signal at an input voltage level to a relatively much higher output voltage while having comparable transistor device sizes for each of the transistors used for the construction of the shifter.

It is another object of the invention to provide a dynamic CMOS level shifter circuit apparatus capable of shifting a signal at an input voltage level to a relatively much higher output voltage while having comparable transistor currents for each of the transistors used for construction of the shifter.

### SUMMARY OF THE INVENTION

In order to achieve the above-identified objects, a dynamic CMOS level shifter circuit apparatus of the invention is provided for shifting a signal of a first logic family at a first lower voltage level to a second higher voltage level for a second logic family in a digital electronic system. The shifter circuit apparatus comprises a first transistor pair that has a first PMOS and a first NMOS transistor connected in series; a second transistor pair that has a second PMOS and a second NMOS transistor connected in series; and a power-down control PMOS transistor. The first and second transistor pairs are connected in parallel, and the parallel connection is connected in series with the power-down control PMOS transistor across the power and ground level of the system. The node at which the drain terminals of the transistors of the first transistor pair is connected together is also connected to the gate of the second PMOS transistor. The node at which the drain terminals of the transistors of the second transistor pair is connected together is also connected to the gate of the first PMOS transistor. Further, the gate terminal of the first NMOS transistor serves as the signal input for the input logic family, and the gate terminal of the first PMOS transistor serves as the shifted output of the shifter circuit apparatus.

### BRIEF DESCRIPTION OF THE DRAWINGS

FIG. 1 is a schematic diagram showing a conventional level shifter circuit for shifting voltages between two logic families of a digital system;

FIG. 2 is a schematic diagram showing a first embodiment of the dynamic level shifter circuit apparatus of the invention;

FIG. 3 is a time diagram showing the switching waveforms of the input, the output, and the control signal for the additional controlling transistor of the shifter circuit apparatus of FIG. 2;

FIG. 4 illustrates the schematic diagram of a second embodiment of the shifter circuit apparatus of the invention with complementary shifted output signals incorporating the use of inverters;

FIG. 5 illustrates the schematic diagram of another embodiment of the shifter circuit apparatus of the invention that is capable of preventing floating input to its inverters;

FIG. 6 illustrates the schematic diagram of yet another embodiment of the shifter circuit apparatus of the invention that is particularly suitable for applications in which the signal voltage difference between the two shifted logic families is excessively large; and

FIG. 7 illustrates the schematic diagram of a shifter circuit apparatus based on the concept of the invention that is suitable for converting digital signals to negative-voltage ratings

### DETAILED DESCRIPTION OF THE INVENTION

FIG. 2 of the drawing is a schematic diagram showing an embodiment of the dynamic level shifter circuit apparatus of the invention. The shifter circuit 200 is used for shifting signal voltages between two logic families of a digital system. The level shifter 200 raises the lower operating signal voltage of the first logic family at its input node 201 to the higher one for the second at its output node 203.

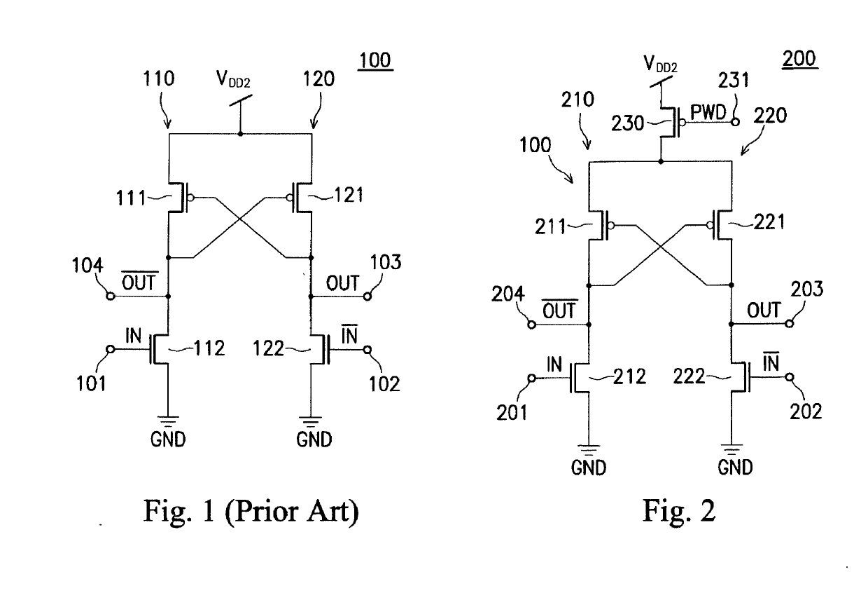

When compared to the prior-art level shifter such as that described in FIG. 1, the level shifter 200 of the invention can be considered to be comprised of a current control transistor and a basic shifter similar to the one described in FIG. 1. As is shown in FIG. 2, the exemplified level shifter circuit apparatus 200 has a basic level shifter circuit generally identified as 100 that is connected in series with a current-controlling PMOS transistor 230 across the power V_{DD2} and ground GND voltage levels.

The basic level shifter circuit 100 comprises two pairs of P- and NMOS FET's generally indicated by reference numerals 210 and 220 respectively. The first pair 210 has a PMOS FET 211 connected in series with an NMOS FET 212, and the second pair 220, similarly with a PMOS FET 221 in series with an NMOS FET 222, is connected in parallel with the first pair. The parallel two pairs of P- and NMOS transistors 210 and 220 are then connected in series with the PMOS transistor 230 across the power V_{DD2} and the ground GND voltage levels.

In both series pairs of P- and NMOS devices of the basic shifter circuit 100, the PMOS FET's 211 and 221 are at the power end, and the NMOS 212 and 222 at the ground end. The P- and NMOS FET's in each pair has their respective drains connected together, the source of the PMOS FET's connected to the power, and that of the NMOS FET's to the ground.

In this first embodiment as shown in FIG. 2, the additional PMOS transistor 230 is used to control the current in the PMOS transistors 211 and 221 in the basic shifter 100. This can be done by providing a power-down control signal (PWD) at the gate terminal 231 of the PMOS transistor 230 for a specified period time during operation. The duration in which this power-down control signal is asserted must be sufficiently long for the NMOS transistors 212 and 222 in the basic shifter 100 to complete their transition as a result of application of the input signal at gate terminal 201 of the input NMOS transistor 212.

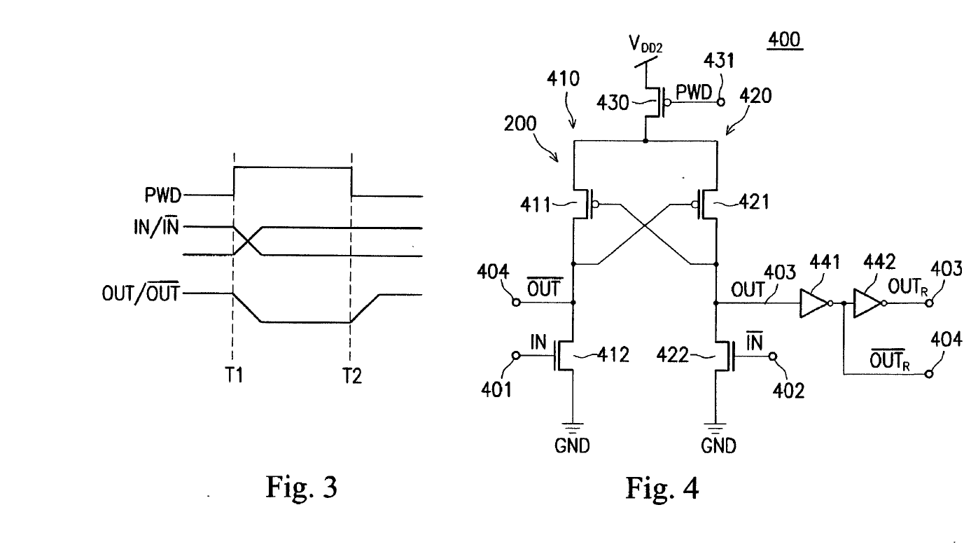

FIG. 3 is a time diagram showing the switching waveforms of the input, the output, as well as the control signal PWD for the PMOS transistor 230 of the shifter circuit apparatus 200 of FIG. 2. The active-high power-down control signal for the PMOS transistor 230 is asserted at time Ti when the level-shifting operation is initiated as the complementary input signals (IN/\overline{IN}) are applied to the input nodes 201 and 202 respectively of the apparatus. As the power-down control signal PWD is asserted, the power to the PMOS transistors 211 and 221 in the basic shifter 100 of FIG. 2 is cut off for a sufficient period of time until time T2, when the NMOS transistors 212 and 222 of the basic shifter 100 settle their state transition.

Thus, in the shifter circuit apparatus of FIG. 2, the presence of this PMOS device 230 prevents the simultaneous conduction of the N- and PMOS transistors in the basic shifter circuitry 100 when level-shifting transition is taking place. The control PMOS transistor 230 serves to cut off current supply to the PMOS transistors 211 and 221 during the transition period of the NMOS transistors 212 and 222. This allows NMOS transistors 212 and 222 to operate independently from their PMOS counterparts. PMOS transistors 211 and 221 are only enabled after their corresponding NMOS transistors 212 and 222 conclude their state transition. The immediate and obvious advantage of the circuit arrangement of FIG. 2 is the avoidance of the requirement that the current handling capability of the NMOS transistors in the basic shifter circuitry 100 be excessively larger than that of the their PMOS counterparts.

Note that a control circuitry capable of implementing the control signal waveform for PWD is not shown in the drawing as such a circuitry is well known to those skilled in the art.

As is seen in the switching waveform of FIG. 3, when the controlling PMOS transistor 230 cuts off the PMOS transistors 211 and 221, electrical status of both the complementary outputs OUT and \overline{OUT} of the shifter circuit apparatus 200 at nodes 203 and 204 respectively become low simultaneously. For some applications such as in TFT LCD, this is not allowable, even for the short duration of time from T1 to T2. This causes logical confusion for subsequent circuitry that require the simultaneous input from both OUT and \overline{OUT}.

To prevent the complementary signals OUT and \overline{OUT} from becoming signals of the same electrical polarity, the node 204 for the signal \overline{OUT} can be abandoned. The complement of the OUT signal may instead be derived from the signal OUT itself at node 203 by the use of, for example, an inverter. FIG. 4 illustrates the schematic diagram of an embodiment of the shifter circuit apparatus of the invention with complementary shifted output signals incorporating the use of inverters.

As is illustrated in FIG. 4, a shifter circuit apparatus 400 in accordance with another embodiment of the invention comprises a shifter 200 and a pair of series-connected inverters 441 and 442. The shifter 200 can be one similar to that described in FIG. 2. The shifted output node 203 of the shifter 200 is connected to the input of the first inverter 441. Output of the first inverter 441 is then connected to the input of the second inverter 442.

The two inverters 441 and 442 are connected in series to provide a reversed and a double-reversed version of the shifted output signal at node 203. The double-reversed signal OUT_{R} at node 403 and the single-reversed signal \overline{OUT_{R}} at node 404 make up the complementary pair of the level-shifted signal for the second logic family of the system. It should be noted that the use of only one inverter is also possible. For example, in the shifter 400 of Figure, the inverter 442 can be removed. In such a configuration, while node 404 produces the reversed output signal \overline{OUT}, the node 203 may still provide the normal shifted output signal OUT. However, two inverters may be required for certain applications when output signal fan out capability is a concern.

There is an occasion when the output node 203 (OUT) of the shifter circuit apparatus 400 of FIG. 4 may become floating. If the previous state of node 203 (the OUT node) was electrically high, and the shifted status remains to be high, i.e., without state transition in the subsequent phase of operation, when the power-down control signal PWD is applied to node 231 of the shifter 400, the NMOS transistor 222 remains off. This results in the floating status of the node 203.

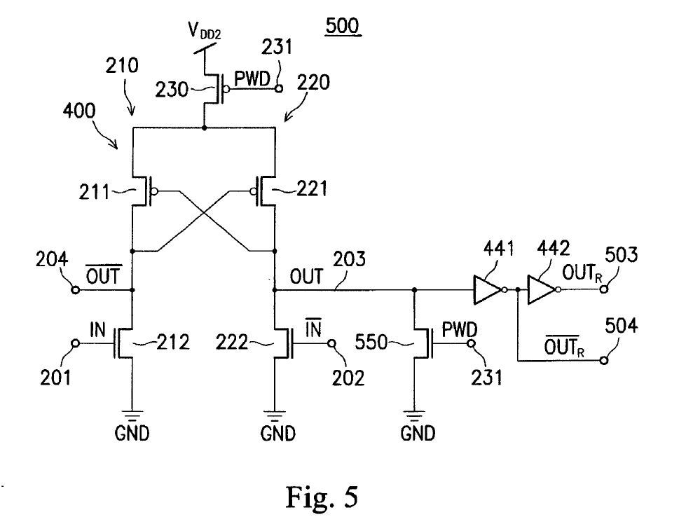

However, a floating input to an inverter such as the inverter 441 directly fed by this node 203 may lead the inverter into a meta-stable status. Large current flows through an inverter in meta-stable mode, an undesirable situation. FIG. 5 shows another embodiment of the shifter circuit apparatus of the invention that is capable of preventing this situation. Another NMOS transistor 550 may be added which controllably connecting the node 203 to ground. This NMOS transistor 550 can be controlled by the same power-down control signal PWD that is fed to the gate terminal of the PMOS transistor 230 at node 231.

Thus, as the power-down control signal PWD cuts off the PMOS transistors 211 and 221, the NMOS transistors 222 which does not change state in this situation may have its node 203 tied virtually to ground since the NMOS transistor 550 is turned on by the PWD control signal at node 231.

Note, however, that means other than NMOS device 550 can be employed as well to achieve the prevention of floating input to the inverter 441 of FIG. 5. For example, a simple resistor that is tied across the input of the inverter 441 (node 203) and ground may equally serve the same function. However, as is aware to those skilled in the art, the fabrication of an NMOS transistor for this purpose is not necessarily more complex and expensive than a resistor.

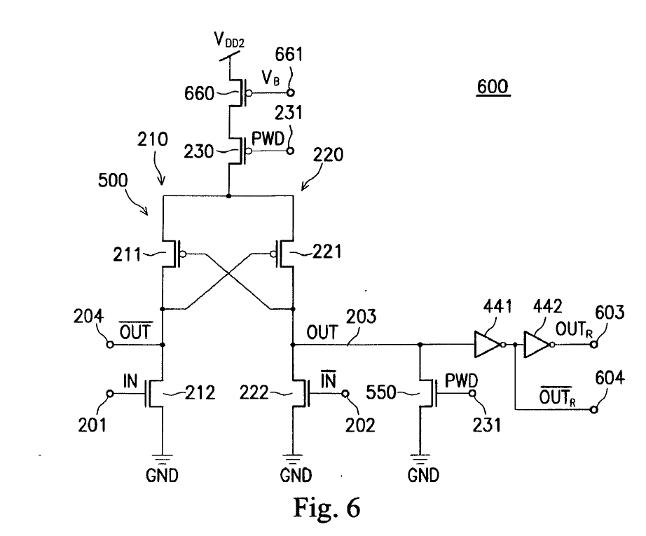

FIG. 6 illustrates another embodiment of the shifter circuit apparatus of the invention that is particularly suitable for applications in which the signal voltage difference between the two shifted logic families is excessively large. For the shifter circuit apparatus of FIGS. 4 and 5, in the extreme situation in which the shifted signal has a voltage level significantly larger than the input, i.e., V_{DD2}>>V_{DD1}, the current in NMOS transistors (212 and 222 of both FIGS. 4 and 5) would be much smaller than that in their PMOS counterparts (211 and 221 of both FIGS. 4 and 5 respectively) in the basic shifter.

This is true as the PMOS and NMOS transistors in the shifters of the invention as exemplified in FIGS. 4 and 5 may enjoy comparable device sizes due to the introduction of the power-down controlling PMOS transistor (230 of both FIGS. 4 and 5). However, as mentioned above, when V_{DD2}>>V_{DD1}, the shifter circuit apparatus embodiments of the invention shown in FIGS. 4 and 5 may experience unproportionally small current in the NMOS transistors as compared to currents in their corresponding PMOS transistors in the shifter.

For example, currents in NMOS transistors 212 and 222 would become much smaller than in PMOS transistors 211 and 221, if V_{DD2} is much higher than V_{DD1} while the device sizes of both the PMOS 211 and 221 and NMOS transistors 212 and 222 in the basic shifter are fabricated of comparable physical scales.

In case the NMOS transistor currents are relatively much smaller than that of their corresponding PMOS counterparts in the basic shifter of, for example, FIG. 5, even if the NMOS transistors had successfully changed state, there is still a risk of transition failure when the PMOS transistors were re-enabled after the assertion of the power-down control signal PWD to the PMOS transistor 230. This is due to the fact that the NMOS currents become ignorable as they are relatively much smaller than the currents in the corresponding PMOS transistors. Such small currents are insufficient for normal operation of the NMOS transistors 212 and 222.

To solve this problem, a further modified shifter circuit apparatus such as that illustrated in FIG. 6 can be used. The shifter 600 of FIG. 6 in accordance with another embodiment of the invention is a modified version of the shifter described above in FIG. 5. Specifically, an additional PMOS transistor 660 is further added and inserted between the shifter 500 of FIG. 5 and the power source V_{DD2}.

This added PMOS transistor 660 is controlled by a bias voltage V_{B}, supplied at node 661 of the shifter circuit apparatus 600. Node 661 is the gate terminal of the PMOS transistor 660. The bias voltage V_{B} controls the transistor 660 to function as a constant current source. As a controlled current source, the PMOS transistor 660 may limit the current flowing through the PMOS transistors 211 and 221, effectively preventing the PMOS currents from becoming too excessive as compared.

Such a shifter circuit apparatus 600 (of FIG. 6) in accordance with the invention is particularly suitable for applications wherein the signal voltage difference between the two interfaced logic families is very large. However, it should be noted that a substantially similar shifter circuit apparatus constructed based on the shifter of either FIG. 2 or 4, with a PMOS transistor inserted between the power source V_{DD2} and its PMOS transistor 230, is also applicable in situations of large voltage-difference signal level shifting.

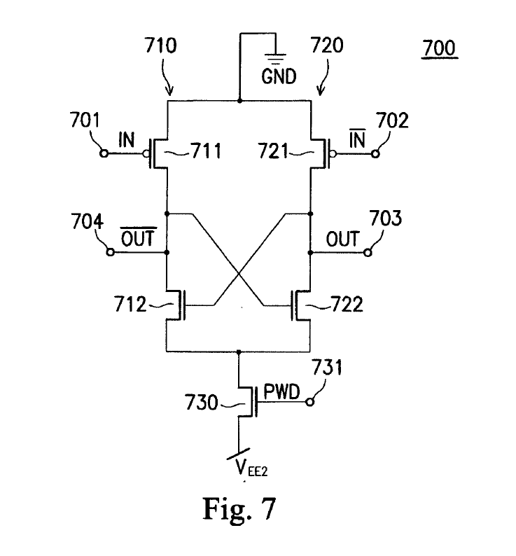

FIG. 7 illustrates a shifter based on the concept of the invention that is suitable for converting digital signals to negative-voltage ratings. Such a shifter 700 has a circuit configuration that is substantially equivalent to the shifter 200 of FIG. 2 except that the P- and NMOS devices are swapped into ones with reverse polarity. The shifter 700, as a result, needs to be tied to a negative-valued voltage V_{EE2} in order to function properly and convert a low-voltage negative signal into a high-voltage negative signal.

As is illustrated in FIG. 7, transistor pairs 710 and 720 are connected in parallel, and the parallel connection is then connected in series with a power-down control NMOS transistor 730 across the power V_{EE2} and ground GND of the system. In this circuit configuration, the control NMOS transistor 730 is connected at the power (V_{EE2}) end, and the PMOS transistors 711 and 721 at the ground end.

The node 704 at which the drain terminals of the transistors 711 and 712 of the transistor pair 710 being connected together is also connected to the gate of the NMOS transistor 722, and the node at which the drain terminals of transistors 721 and 722 of the transistor pair 720 being connected together is also connected to the gate of the NMOS transistor 712.

The gate terminal of the PMOS transistor 711 serves as the signal input for the input logic family. The gate terminal of the NMOS transistor 712 serves as the shifted output of the shifter circuit apparatus 700. The gate terminal 731 of the power-down control NMOS transistor 730 is controlled by a power-down control signal PWD to cut off the NMOS transistors 712 and 722 for a duration of time sufficient for the PMOS transistors 711 and 721 to settle their state transition. The timing control, as is easily understood for those skilled in the art, may be implemented in the scheme similar to that illustrated in FIG. 3.

Embodiments of the shifter circuit apparatus of the invention similar to the ones depicted in FIGS. 4, 5 and 6 but with polarity-reversed FET devices are similarly possible.

Although the invention has been described in considerable detail with reference to the preferred version thereof, other versions are within the scope of the present invention. Therefore, the spirit and scope of the appended claims should not be limited to the description of the preferred version contained herein.

What is claimed is:

1. A dynamic CMOS level shifter circuit apparatus in a digital electronic system for shifting a signal of a first logic family at a first lower voltage level to a second higher voltage level for a second logic family, said shifter circuit apparatus comprising:
a first transistor pair comprising a first PMOS and a first NMOS transistor connected in series;
a second transistor pair comprising a second PMOS and a second NMOS transistor connected in series; and
a power-down control PMOS transistor; wherein:
said first and second transistor pairs are connected in parallel, and said parallel connection is connected in series with said power-down control PMOS transistor across the power and ground levels of said system, wherein said control PMOS transistor is connected at the power end, and said first and second NMOS transistors at the ground end;
the node at which the drain terminals of said transistors of said first transistor pair being connected together is also connected to the gate of said second PMOS transistor, and the node at which the drain terminals of said transistors of said second transistor pair being connected together is also connected to the gate of said first PMOS transistor; and
the gate terminal of said first NMOS transistor serves as the signal input for said input logic family; the gate terminal of said first PMOS transistor serves as the shifted output of said shifter circuit apparatus; and the gate terminal of said power-down control PMOS transistor is controlled by a power-down control signal to cut off said first and second PMOS transistors for a duration of time sufficient for said first and second NMOS transistors to settle state transition.

2. The shifter circuit apparatus of claim 1, further comprising a first inverter and a second inverter, wherein said first and second inverters are connected in series, the input of said first inverter is connected to said output, and the output of said first inverter and the output of said second inverter generate a complementary pair of said shifted output.

3. A dynamic CMOS level shifter circuit apparatus in a digital electronic system for shifting a signal of a first logic family at a first lower voltage level to a second higher voltage level for a second logic family, said shifter circuit apparatus comprising:
a first transistor pair comprising a first PMOS and a first NMOS transistor connected in series;
a second transistor pair comprising a second PMOS and a second NMOS transistor connected in series;
a power-down control PMOS transistor; and
a first inverter and a second inverter; wherein:
said first and second transistor pairs are connected in parallel, and said parallel connection is connected in series with said power-down control PMOS transistor across the power and ground levels of said system, wherein said control PMOS transistor is connected at the power end, and said first and second NMOS transistors at the ground end;
the node at which the drain terminals of said transistors of said first transistor pair being connected together is also connected to the gate of said second PMOS transistor, and the node at which the drain terminals of said transistors of said second transistor pair being connected together is also connected to the gate of said first PMOS transistor; and
the gate terminal of said first NMOS transistor serves as the signal input for said input logic family; the gate terminal of said first PMOS transistor is connected to the input of said first inverter; the output of said first inverter is connected to the input of said second inverter; the output of said second inverter serves as the shifted output of said shifter circuit apparatus; and the gate terminal of said power-down control PMOS transistor is controlled by a power-down control signal to cut off said first and second PMOS transistors for a duration of time sufficient for said first and second NMOS transistors to settle state transition.

4. The shifter circuit apparatus of claim 3, further comprising a third PMOS transistor, wherein the drain and source terminals of said third NMOS transistor are connected respectively to the input of said first inverter and the ground of said system.

5. The shifter circuit apparatus of claim 3, further comprising a resistor connected across the input of said first inverter and the ground of said system.

6. A dynamic CMOS level shifter circuit apparatus in a digital electronic system for shifting a signal of a first logic family at a first lower voltage level to a second higher voltage level for a second logic family, said shifter circuit apparatus comprising:
a first transistor pair comprising a first PMOS and a first NMOS transistor connected in series;
a second transistor pair comprising a second PMOS and a second NMOS transistor connected in series;
a power-down control PMOS transistor;
a first inverter and a second inverter; and
a third NMOS transistor; wherein:
said first and second transistor pairs are connected in parallel, and said parallel connection is connected in series with said power-down control PMOS transistor across the power and ground levels of said system, wherein said control PMOS transistor is connected at the power end, and said first and second NMOS transistors at the ground end;
the node at which the drain terminals of said transistors of said first transistor pair being connected together is also connected to the gate of said second PMOS transistor, and the node at which the drain terminals of said transistors of said second transistor pair being connected together is also connected to the gate of said first PMOS transistor; and
the gate terminal of said first NMOS transistor serves as the signal input for said input logic family; the gate terminal of said first PMOS transistor is connected to the input of said first inverter; the output of said first inverter is connected to the input of said second inverter; and the output of said second inverter serves as the shifted output of said shifter circuit apparatus; the drain and source terminals of said third NMOS transistor are connected respectively to the input of said first inverter and the ground of said system; and the gate terminal of said power-down control PMOS transistor is controlled by a power-down control signal to cut off said first and second PMOS transistors for a duration of time sufficient for said first and second NMOS transistors to settle state transition.

7. The shifter circuit apparatus of claim 1, further comprising a third PMOS transistor connected between the power level of said system and said power-down control PMOS transistor.

8. A dynamic CMOS level shifter circuit apparatus in a digital electronic system for shifting a signal of a first logic family at a first lower voltage level to a second higher voltage level for a second logic family, said shifter circuit apparatus comprising:
a first transistor pair comprising a first PMOS and a first NMOS transistor connected in series;
a second transistor pair comprising a second PMOS and a second NMOS transistor connected in series;
a third PMOS transistor; and
a power-down control PMOS transistor; wherein:
said first and second transistor pairs are connected in parallel, and said parallel connection is connected in series with said power-down control PMOS transistor and said third PMOS transistor across the power and ground levels of said system, wherein said third PMOS transistor is connected at the power end, and said first and second NMOS transistors at the ground end;
the node at which the drain terminals of said transistors of said first transistor pair being connected together is also connected to the gate of said second PMOS transistor, and the node at which the drain terminals of said transistors of said second transistor pair being connected together is also connected to the gate of said first PMOS transistor; and
the gate terminal of said first NMOS transistor serves as the signal input for said input logic family; the gate terminal of said first PMOS transistor serves as the shifted output of said shifter circuit apparatus; and the gate terminal of said power-down control PMOS transistor is controlled by a power-down control signal to cut off said first and second PMOS transistors for a duration of time sufficient for said first and second NMOS transistors to settle state transition.

9. The shifter circuit apparatus of claim 8, wherein said third PMOS transistor is a constant current source.

10. A dynamic CMOS level shifter circuit apparatus in a digital electronic system for shifting a signal of a first logic family at a first lower voltage level to a second higher voltage level for a second logic family, said shifter circuit apparatus comprising:
a first transistor pair comprising a first NMOS and a first PMOS transistor connected in series;
a second transistor pair comprising a second NMOS and a second PMOS transistor connected in series; and
a power-down control NMOS transistor; wherein:
said first and second transistor pairs are connected in parallel, and said parallel connection is connected in series with said power-down control NMOS transistor across the power and ground levels of said system, wherein said control NMOS transistor is connected at the power end, and said first and second PMOS transistors at the ground end;
the node at which the drain terminals of said transistors of said first transistor pair being connected together is also connected to the gate of said second NMOS transistor, and the node at which the drain terminals of said transistors of said second transistor pair being connected together is also connected to the gate of said first NMOS transistor; and
the gate terminal of said first PMOS transistor serves as the signal input for said input logic family; the gate terminal of said first NMOS transistor serves as the shifted output of said shifter circuit apparatus; and the gate terminal of said power-down control NMOS transistor is controlled by a power-down control signal to cut off said first and second NMOS transistors for a duration of time sufficient for said first and second PMOS transistors to settle state transition.
